(19) United States
(12) Patent Application Publication
(10) Pub. No.: US 2012/0266957 A1
(43) Pub. Date: Oct. 25, 2012

(54) ORGANIC PHOTOVOLTAIC CELL WITH POLYMERIC GRATING AND RELATED DEVICES AND METHODS

(75) Inventors: Xizu Wang, Singapore (SG); Hoi Lam Tam, Hong Kong (HK); Wei Peng Goh, Singapore (SG); Zhikuan Chen, Singapore (SG); Furong Zhu, Hong Kong (HK)

(73) Assignee: Agency for Science, Technology and Research, Connexis (SG)

(21) Appl. No.: 13/452,342

(22) Filed: Apr. 20, 2012

Related U.S. Application Data
(60) Provisional application No. 61/477,373, filed on Apr. 20, 2011.

(51) Int. Cl. H01L 51/44; H01L 51/48; H01L 31/0232

(52) U.S. Cl. 136/259; 136/263; 438/82; 257/E51.012

(57) ABSTRACT

A photovoltaic cell comprises first and second electrode layers, an organic photoactive layer between the first and second electrode layers, and a polymeric grating structure in the first electrode layer. The first and second electrode layers are configured to collect electrical charges from the photoactive layer and to allow light to transmit through the first electrode layer to reach the photoactive layer. The grating structure is configured to provide a grating periodicity of about 100 nm to about 500 nm and grating amplitude of about 100 nm to about 500 nm. A device comprising the photovoltaic cell is disclosed. A photovoltaic cell may be formed by printing a polymer on a substrate to form a grating structure, forming a first electrode layer on the polymeric grating structure and the substrate, forming an organic photoactive layer above the first electrode layer, and forming a second electrode layer above the photoactive layer.

### CROSS-REFERENCE TO RELATED APPLICATION

This application claims the benefit of, and priority from, U.S. Patent Application Ser. No. 61/477,373, filed Apr. 20, 2011, and entitled “Light in-coupling in organic photovoltaic devices,” the entire contents of which are incorporated herein by reference.

### FIELD

The present invention relates generally to photovoltaic cells and devices and related methods, and particularly to organic photovoltaic materials and devices and related methods.

### BACKGROUND

Organic photovoltaic (OPV) cells and devices containing OPV cells are useful for converting light to electrical energy and have a wide range of applications. A typical photovoltaic cell (also referred to as solar cell) has a photoactive layer between two electrode layers, where at least one of the electrode layers is transparent. It is also common to form a photovoltaic cell on a substrate. The photoactive layer may be a single layer or contain multiple sub-layers. For example, in an OPV cell, the photoactive layer may contain one or more organic photoactive materials. The organic photoactive layer may contain a conjugated polymer, or an electron donor material and an electron acceptor material. The electron donor and acceptor may be provided in separate layers or may be blended or incorporated into one layer. Electron donors and acceptors can be provided by conjugated polymers or organic small molecules. A typical transparent anode material is indium-tin-oxide (ITO).

As compared to silicon-based photovoltaic technology, solar cells based on conjugated polymers or organic small molecules can offer an attractive alternative due to their ease for large-area processing and compatibility with low cost flexible substrates, and due to the high degree of control that can be achieved over the optoelectronic properties of the conjugated polymers and organic small molecules. However, the quantum efficiency of many conventional organic photovoltaic (OPV) cells is relatively low, as compared to silicon-based photovoltaic cells. To increase efficiency, a bulk heterojunction (BHJ) structure has been used due to its larger interfacial area between the donor and the acceptor.

### BRIEF DESCRIPTION OF THE DRAWINGS

In the figures, which illustrate, by way of example only, embodiments of the present invention:

FIG. 1 is a schematic perspective view of an organic photovoltaic (OPV) cell, exemplary of an embodiment of the present invention;

FIG. 2 is a schematic diagram illustrating diffraction of light through layers of the OPV cell of FIG. 1;

FIG. 3 is a schematic cross-sectional elevation view of an OPV cell with a substrate, exemplary of an embodiment of the present invention;

FIG. 4 is a schematic cross-sectional elevation view of another OPV cell with a substrate, exemplary of an embodiment of the present invention;

FIG. 5 is a schematic cross-sectional elevation view of a further OPV cell with a substrate, exemplary of an embodiment of the present invention;

FIG. 6 is a schematic diagram illustrating a process for forming an OPV cell, exemplary of an embodiment of the present invention;

FIG. 7 is a schematic diagram illustrating the operation of an OPV cell, exemplary of an embodiment of the present invention;

FIG. 8 is an screen shot image showing atomic force microscopy (AFM) imaging data measured from a sample OPV cell;

FIG. 9 is a data graph showing J-V curves measured from sample OPV cells with polymeric photoactive layers;

FIG. 10 is a data graph showing incident photon-to-electron conversion efficiencies (IPCE) measured from the sample OPV cells of FIG. 9;

FIG. 11 is a data graph showing J-V curves measured from sample OPV cells with small molecule photoactive layers;

FIG. 12 is a data graph showing IPCE measured from sample OPV cells of FIG. 11; and

FIG. 13 is an image of sample OPV cells.

### DETAILED DESCRIPTION

In an aspect of the present disclosure, there is provided a photovoltaic cell. The photovoltaic cell comprises a first electrode layer and a second electrode layer; an organic photoactive layer between the first and second electrode layers; and a polymeric grating structure in the first electrode layer. The first and second electrode layers are configured to collect electrical charges from the photoactive layer and to allow light to transmit through the first electrode layer to reach the photoactive layer. The grating structure is configured to provide a grating periodicity of about 100 nm to about 500 nm and grating amplitude of about 100 nm to about 500 nm. The polymeric grating structure may be formed from a poly(methyl methacrylate). The first electrode layer may comprise a transparent conducting oxide (TCO), such as indium-tin-oxide (ITO). The first electrode layer may have a thickness of about 100 nm to about 500 nm. The polymeric grating structure may be printed on a substrate, and the first electrode layer may be formed on the substrate and the polymeric grating structure. The substrate may be formed of glass. The organic photoactive layer may comprise a polymeric photoactive material or a small molecule photoactive material. The photovoltaic cell may also comprise a charge transporting layer disposed between the photoactive layer and one of the first and second electrode layers.

In another aspect of the present disclosure, there is provided a device comprising a photovoltaic cell disclosed herein.

In a further aspect of the present disclosure, there is provided a method of forming a photovoltaic cell. The method comprises printing a polymer on a substrate to form a grating structure; forming a first electrode layer on the polymeric grating structure and the substrate; forming an organic photoactive layer above the first electrode layer; and forming a second electrode layer above the photoactive layer. The first electrode layers allows transmission of light therethrough to reach the photoactive layer and the grating structure provides a grating periodicity of about 100 nm to about 500 nm and a grating amplitude of about 100 nm to about 500 nm. The polymer may be a poly(methyl methacrylate). The first electrode layer may comprise a TCO, such as ITO. The first electrode layer may be formed at a temperature below 60° C. by sputtering. The first electrode layer may be formed to have a thickness of about 100 nm to about 500 nm. The substrate may be formed of glass. The organic photoactive layer may comprise a polymeric photoactive material or a small molecule photoactive material. A charge transporting layer may be formed between the photoactive layer and one of the first and second electrode layers.

In an aspect of the present disclosure, there is provided a photovoltaic cell. The photovoltaic cell comprises a transparent substrate, a transparent polymeric nanostructure printed on the substrate, a transparent conductive film formed over the nanostructure on the substrate, an organic photoactive layer above the transparent conductive film, and a conductor above the photoactive layer. The transparent conductive film has a textured surface. The transparent nanostructure and conductive film diffract light transmitted therethrough, and may provide a grating periodicity of about 100 nm to about 500 nm and a grating amplitude of about 100 nm to about 500 nm.

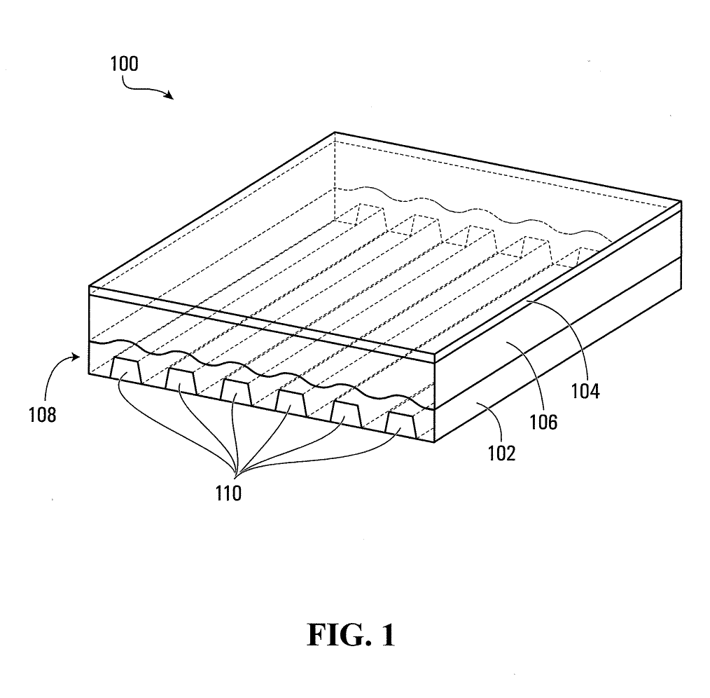

An embodiment of a photovoltaic cell is schematically illustrated in FIG. 1. The depicted photovoltaic cell 100 has a first electrode layer 102, a second electrode layer 104, and a photoactive layer 106 between electrode layers 102, 104. One or both of electrode layers 102, 104 may be formed of a material selected to allow light to transmit therethrough to reach the photoactive layer. For the purpose of illustration below, it is assumed that at least electrode layer 102 is transparent to allow light transmission therethrough, and a polymeric grating structure 108 is provided in electrode layer 102. It should be understood that in different embodiments, a grating structure may be provided in each transparent electrode layer when multiple transparent electrode layers are provided.

Electrode layers 102, 104 are selected and configured so that one of them can function as an anode and the other can function as a cathode to collect electrical charges from photoactive layer 106. Electrode layers 102, 104 may thus be formed from respective materials that are known to those skilled in the art to be suitable for use as anode and cathode electrodes in an organic photovoltaic cell. For example, suitable materials for forming an anode layer may include ITO, fluorine-tin-oxide (FTO), zinc-indium-oxide (ZIO), or the like. Suitable materials for forming a cathode layer may include silver (Ag), aluminum (Al), calcium (Ca), or the like.

Electrode layer 102 may be a transparent conducting layer, and may be formed from a TCO and shaped to increase light diffraction. A TCO layer may be a graded TCO layer.

A transparent conducting layer may be formed from one or more of ITO, zinc-indium-oxide, aluminum-doped zinc oxide, Ga—In—Sn—O, SnO₂, Zn—In—Sn—O, Ga—In—O, TiNbO, ZSO, NiOₓ, or any combination of transparent conducting oxides.

In some embodiments, electrode layer 102 may be formed of an anode material, such as ITO. An ITO layer may be formed to exhibit relatively high electric conductivity and optical transparency as compared to some other anode materials. For example, a 130 nm thick ITO film may exhibit an electrical sheet resistance of 25±5 Ω/sq and an average light transmittance of above 85%. Electrode layer 104 may be formed of a cathode material, such as Ag.

In other embodiments, ITO may be replaced with another conductive material that has suitable electric conductivity and optical transparency for the particular application, or has electric conductivity and optical transparency similar to those of ITO.

As depicted in FIG. 1, the interface between electrode layer 102 and photoactive layer 106 has a wave-like profile, resulting from the presence of grating structure 108. This wave-like profile may be shaped to promote diffraction of light, and potentially facilitate coupling of surface plasmon resonance (SPR).

Electrode layer 104 may be formed of any suitable electrode materials, including suitable metals, alloys, or metal oxides. In some embodiments, electrode layer 104 may be transparent and may include a graded TCO layer.

Photoactive layer 106 may be formed from one organic material or different materials that exhibit photochemical reactivity. A material is photoactive if it can absorb light or photons and undergo chemical reactions upon photon absorption to produce excitons, so that electrical charges can be collected from the material to generate electrical power. An organic photoactive layer may be formed from organic semiconductors, and may include multiple sub-layers. Known organic photoactive materials include photoactive polymers, such as conjugated polymers, and photoactive small-molecules. Photoactive layer 106 may also include electron donor and acceptor pairs, which may be provided in separate layers or may be blended or incorporated into one layer. Electron donors and acceptors can be provided by conjugated polymers or organic small molecules. In some embodiments, photoactive layer 106 may include a donor sub-layer and an acceptor sub-layer. Typically, the donor sub-layer may be adjacent to the anode electrode layer and the acceptor sub-layer may be adjacent to the cathode electrode layer. In some embodiments, continuous heterojunctions may be formed between donor and acceptor sub-layers to facilitate charge separation and transport.

In some embodiments, organic photoactive layer 106 may be formed from one or more conjugated polymers. Example photoactive conjugated polymers that can serve as an electron donor include poly-3(hexyl-thiophene) (P3HT), poly-[2-(3,7-dimethyloctyloxy)-5-methyloxy]-para-phenylene-vinylene (MDMO-PPV), poly[[9-(1-octylnonyl)-9H-carbazole-2,7-diyl]-2,5-thiophenediyl-2,1,3-benzothiadiazole-4,7-diyl-2,5-thiophenediyl] (PCDTBT), poly[2,1,3-benzothiadiazole-4,7-diyl[4,4-bis(2-ethylhexyl)-4H-cyclopenta[2,1-b:3,4-b′]dithiophene-2,6-diyl]] (PCPDTBT), or the like.

Example photoactive conjugated polymers that can serve as an electron acceptor include [6,6]-phenyl-C₆₁-butyric acid methyl ester ([60]PCBM), [6,6]-phenyl-C₇₁-butyric acid methyl ester ([C70]PCBM), indene-C60 bisadduct (ICBA), or the like.

In some embodiments, organic photoactive layer 106 may be formed from one or more small molecule compounds. An example donor material is metal phthalocyanines (Pc), such as ZnPc, CuPc, ClAlPc, SubPc, and examples of acceptor materials include fullerene C₆₀, C₇₀, or the like.

The thickness of each layer 102, 104, 106 may be selected depending on the particular embodiment and application for which the photovoltaic cell is to be used by those skilled in the art based on known design techniques and criteria. In some embodiments, electrode layer 102 may have a thickness of about 50 nm to about 200 nm, electrode layer 104 may have a thickness of about 60 nm to about 200 nm, and photoactive layer 106 may have an overall thickness of about 50 nm to about 300 nm. In selected embodiments, photoactive layer 106 may have an overall thickness of less than 300 nm.

As can be understood by those skilled in the art, when the thickness of photoactive layer 106 is increased, the amount of light absorption may increase but the power conversion efficiency (PCE) may decrease. Unit production costs may also increase with a thicker layer. Thus, in some embodiments, the thickness of photoactive layer 106 may be selected or optimized based on a number of factors to be considered in the particular application, including the factors discussed above.

In a particular embodiment, electrode layer 102 may have a thickness of about 130 nm, electrode layer 104 may have a thickness of about 100 nm, and photoactive layer 106 may have a thickness of about 200 nm.

In another particular embodiment, electrode layer 102 may have a thickness of about 150 nm, electrode layer 104 may have a thickness of about 120 nm, and photoactive layer 106 may have a thickness of about 80 nm.

Suitable materials for electrode layers 102, 104 and photoactive layer 106 in a particular embodiment can be selected by those skilled in the art depending on the particular application based on knowledge known to the skilled person. The techniques for making such materials and forming the respective layers are also within the knowledge of those skilled in the art.

Grating structure 108 is formed from a polymer material, such as poly(methyl methacrylate) (PMMA).

In other embodiments, a polycarbonate or another thermoplastic polymer suitable for forming a resist may be used to form grating structure 108. A suitable polymer for forming grating structure 108 can be processed to form and retain the desired surface profile and can diffract light. In a given particular application, the skilled person in the art will be able to select suitable materials based on the guidance provided in this disclosure and their knowledge.

Grating structure 108 is configured to provide a grating periodicity of about 100 nm to about 500 nm and a grating amplitude of about 100 nm to about 500 nm.

As depicted, grating structure 108 may include ridges 110. Each ridge 110 may have a generally rectangular cross-section with a width of about 100 nm to about 500 nm and a height of about 10 nm to about 300 nm. In some embodiments, each ridge 110 nm may have a width of about 250 nm and a height of about 100 nm. In selected embodiments, ridges 110 may cover an area with an overall dimension of 1 cm by 1 cm.

In different embodiments, grating structure 108 may include elongated structures that have different shapes and dimensions. For example, ridges 110 may be replaced with ridges that have generally square, circular, oval, triangular, or trapezoidal cross-sections.

The dimensions and shapes of the grating structure may be selected depending on the types of photoactive materials used, with a view to promote light diffraction and SPR coupling.

Ridges 110 or similar structures may be separated from one another as depicted or may be connected by, e.g., a thin layer.

Grating structure 108 may be formed using any suitable technique. In some embodiments, ridges 110 may be formed using a nano-printing technique, as will be described below.

Experimental results (see Example section below) have shown that grating structure 108 can enhance light absorption in photovoltaic cell 100 and thus increase the PCE of photovoltaic cell 100.

Without being limited to any particular theory, it is expected that light absorption in photovoltaic cell 100 is increased due to diffraction of light by grating structure 108, which leads to increased optical path length in photoactive layer 106.

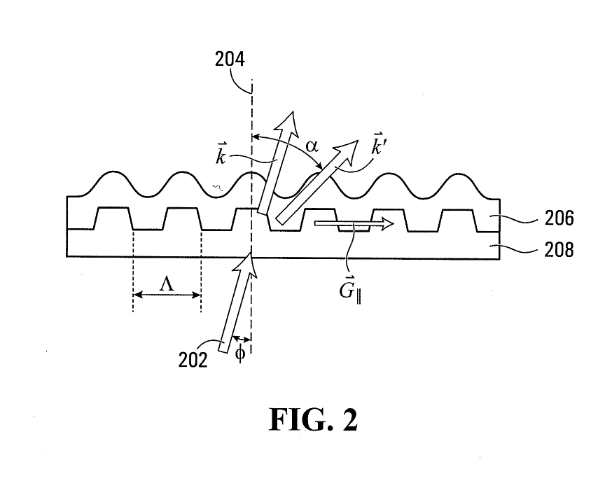

For diffraction grating in a grating configuration as depicted in FIG. 2, which includes an active layer 206 above a grating structure 208, the periodicity of grating structure 208 at a given wavelength and the diffracted angle can be calculated using Equation (1):

$$\frac{2 π}{λ} \cdot {n}_{air} sin θ + \frac{2 π}{Λ} = \frac{2 π}{λ} \cdot {n}_{core} sin α , \qquad ( 1 )$$

where θ is the incident angle of incident light 202, α is the diffracted angle, λ is the diffracted wavelength, Λ is the periodicity, nₐᵢᵣ and n_{core} are the refractive indices of the respective medium (air or the core). In FIG. 2, the normal axis perpendicular to the incident surface is depicted as axis 204, and the in-plane components are depicted, where \vec{k}_{∥} is the zero order emission (k), \vec{G}_{∥} is the wave vector, which is the same for both media at the grating interface, \vec{k}_{∥}′ is the first order diffracted emission, and \vec{k}_{∥}′=\vec{k}_{∥}+\vec{G}_{∥}. When the incident light is perpendicular to the photoactive layer surface, the optical path length is equal to the thickness of the photoactive layer. When the light is incident at an angle, the optical path length is longer than the thickness of the photoactive layer. Thus, due to the diffraction effect of the grating structure, the average optical path length is increased by the presence of the grating structure.

In some embodiments where electrode layer 104 includes a suitable metal cathode, it is also possible that incident light diffracted by grating structure 108 can be coupled to surface plasmon resonance at the interface between electrode layer 104 and organic photoactive layer 106. In such cases, electrons can be driven to oscillate and interact with incident light in localized surface plasmon resonance (metal nanoparticles) or propagating surface plasmon resonance (metal surfaces). It is expected that plasmon excitation energy can be strongly localized at a metal/dielectric interface. Within the skin depth (usually 100 nm to 200 nm for a thin organic layer) of the electric field of plasmon excitation, the energy of plasmon excitation can be efficiently absorbed. Such a phenomenon may serve to improve the PCE of an OPV cell.

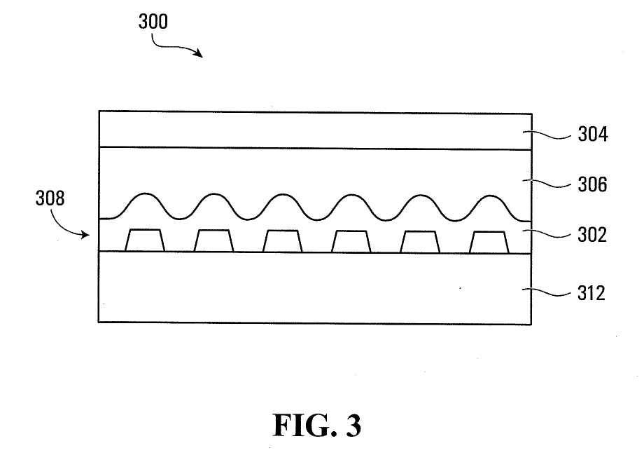

A further embodiment of a photovoltaic cell is schematically illustrated in FIG. 3. As depicted in FIG. 3, a photovoltaic cell 300 may include electrode layers 302, 304, an organic photoactive layer 306, and a grating structure 308, which are formed on a substrate 312.

The description above regarding electrode layers 102, 104, photoactive layer 106, and grating structure 108 also applies to electrode layers 302, 304, photoactive layer 306, and grating structure 308.

Substrate 312 may be transparent and may be formed of glass. Substrate 312 may also be formed of other suitable materials such as clear plastics and glass substrates. In some embodiments, a flexible material may be used to form substrate 312. In some embodiments, the material for the transparent substrate may be selected so that it can form a proper permeation barrier layer suitable for the particular application, such as applications in organic light-emitting diode (OLED) devices, polymer light-emitting diode (PLED) devices or other OPV devices.

Conveniently, grating structure 308 may be initially printed on substrate 312, as will be further described below.

In some embodiments, an OPV cell may be formed on a substrate that is rigid. In different embodiments, an OPV cell may be formed on a substrate that is flexible. The substrate may be opaque or transparent depending on the particular requirements of the particular application.

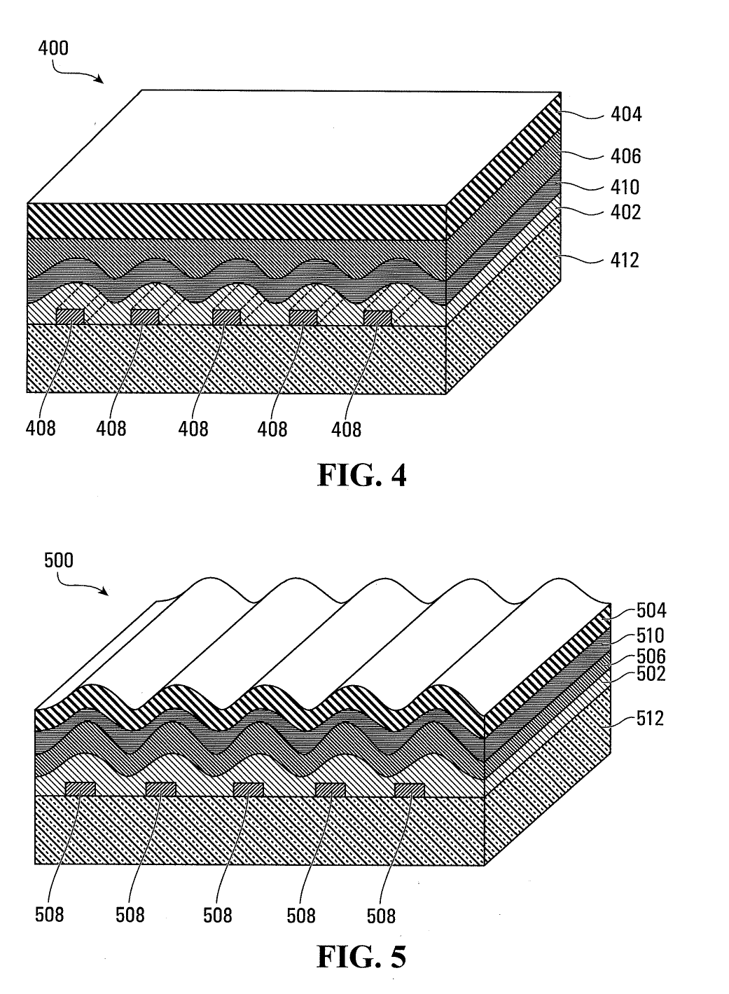

A further embodiment of a photovoltaic cell is schematically illustrated in FIG. 4. As depicted in FIG. 4, a photovoltaic cell 400 may include electrode layers 402, 404, an organic photoactive layer 406, a grating structure 408, and a hole transporting layer 410, which are formed on a substrate 412.

The description above regarding electrode layers 102, 104, photoactive layer 106, and grating structure 108 and substrate 312 also applies to electrode layers 402, 404, photoactive layer 406, grating structure 408, and substrate 412.

Hole transporting layer 410 may be formed of poly(3,4-ethylenedioxythiophene) (PEDOT:PSS) and may have a thickness of about 40 nm. Hole transporting layer 410 may also be formed of other suitable materials such as MoO₃ or ZnO.

Hole transporting layer 410 can have the effect of smoothening the interface between electrode layer 402 and photoactive layer 406, which may help to improve hole injection from photoactive layer 406 into electrode layer 402.

With hole transporting layer 410, polymer materials such as P3HT:PCBM, PCDTBT:PCBM, or the like, may be conveniently used as the photoactive materials in layer 406.

A further embodiment of a photovoltaic cell is schematically illustrated in FIG. 5. As depicted in FIG. 5, a photovoltaic cell 500 may include electrode layers 502 and 504, an organic photoactive layer 506, a grating structure 508, and an electron transporting layer 510, which are formed on a substrate 512.

The description above regarding electrode layers 102, 104, photoactive layer 106, and grating structure 108 and substrate 312 also applies to electrode layers 502, 504, photoactive layer 506, grating structure 508, and substrate 512.

Electron transporting layer 510 may be formed of bathophenanthroline (BPhen) and may have a thickness of about 8 nm. Electron transporting layer 510 may also be formed of other suitable materials such as C₆₀ or C₇₀.

Electron transporting layer 510 can help to improve electron injection from photoactive layer 506 into electrode layer 504.

With electron transporting layer 510, small molecules such as CuPc:C₆₀), ZnPc:C₆₀, or the like, may be conveniently used as the photoactive materials in layer 506.

An electron transporting material is also referred to as an electron injector layer. An electron injector layer may be formed with a thin (such as about 0.5 to about 10 nm) layer of a low work-function metal, metal alloy or contact material that is suitable for electron injection or collection. Some known low work-function metals and metal alloys include Ca, Li, Ba, Mg, Al, LiF/Al, and Ag.

In some embodiments of the present invention, a grating structure, such as grating structures 108, 308, 408, 508, can be formed by printing the grating material on to a substrate, such as substrates 312, 412, 512. Known lithography techniques, particularly micro- or nano-lithography techniques, for printing polymeric materials may be utilized for printing the grating structure on the substrate. For example, suitable nano-lithography techniques are disclosed in L. J. Guo, “Nanoimprint Lithography: Methods and Material Requirements,” Adv. Mater. 2007, vol. 19, pp. 495-513 (referred to as “Guo” hereinafter); and A. Pimpin and W. Srituravanich, “Review on Micro- and Nanolithography Techniques and their Applications,” Engineering Journal, vol. 16, pp. 37-55 (referred to as “Pimpin” hereinafter), the entire contents of each of which are incorporated herein by reference. In some embodiments, solution based lithography techniques may be conveniently used.

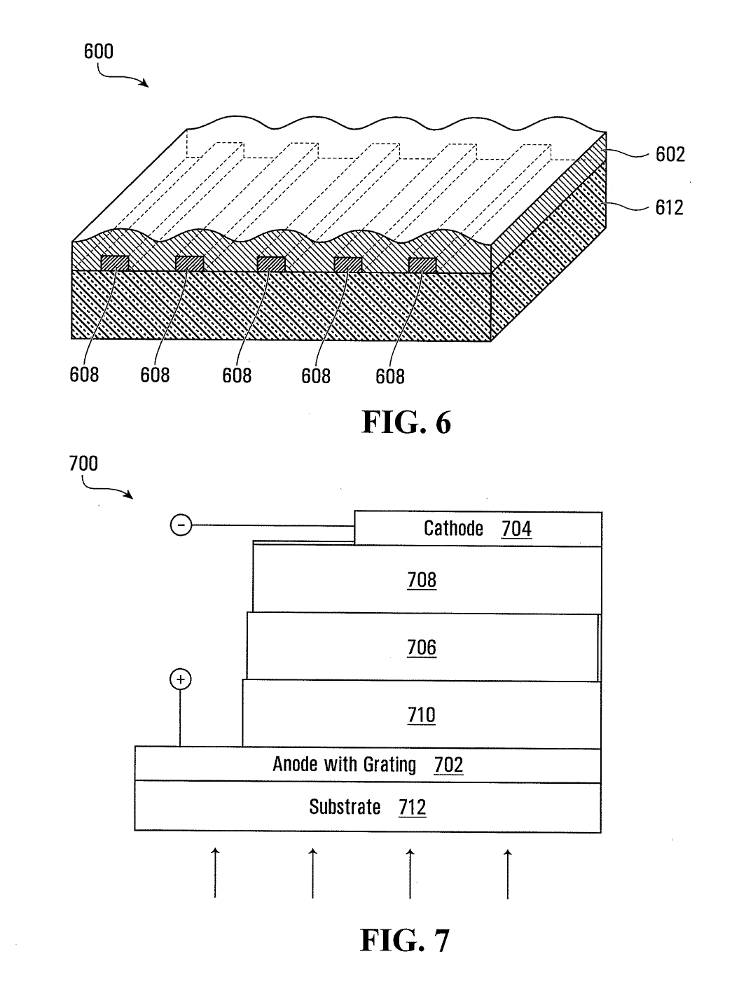

In selected embodiments, a grating structure may be formed on a substrate as illustrated in FIG. 6, using nanoimprint lithography. As a skilled person can appreciate, in general nanoimprint lithography can provide a simple lithography process with low cost, high throughput and high resolution. Example nanoimprint lithography processes include thermoplastic nanoimprint lithography and photo nanoimprint lithography. The imprinting process may be a full wafer nanoimprint process or a step and repeat nanoimprint process. Other suitable techniques include electron-beam etching and photolithography.

The grating structure may be formed according to the techniques described in Guo or Pimpin. When the grating structure is formed using a Si mold, the shapes and dimensions of the grating structures may be controlled by modifying the shape of the Si mold.

After grating structure 608 is imprinted onto substrate 612. An electrode layer 602 may be formed on top of substrate 612 and grating structure 608 using a low-temperature process.

For example, in a selected embodiment, a 100 nm thick PMMA (2.5% wt in toluene) layer may be spin-coated onto a glass substrate. The coated substrate may be annealed at about 120° C. for about 2 min. A Si mold with a grating pattern may be pressed onto the PMMA coated substrate at a pressure of 60 bars at about 140° C. A grating structure is formed after releasing the mold from the coated substrate.

A high performance Low-Temperature ITO (LT-ITO) anode layer (combination of radio frequency (RF) and direct current (DC) sputtering) may be overlaid on the PMMA grating structure and on the glass substrate at a low processing temperature of less than about 60° C., to form a base structure 600.

Further description of a suitable low temperature process can be found in, e.g., WO2009136863 to Zhu et al.; and WO2008/123833 to Zhu et al., the entire contents of each of which are incorporated herein by reference.

Conveniently, in some embodiments, an ITO layer may be formed at relatively low temperatures, such as below about 60° C. The resulting ITO layer may have the sheet resistance of about 25 Ω/sq and average transparency of about 85% or more.

Next, the additional layers including a photoactive layer, a top electrode layer, and any intermediate layers such as electron or hole transporting layers may be formed on top of electrode layer 602 in a desired sequence according to known techniques for forming such layers.

For example, a polymeric layer and its corresponding hole transporting layer may be formed by spin-coating, spray-coating, blade-coating, or a similar coating process. A small molecules layer and its corresponding electron transporting layer may be formed by thermal evaporation in a vacuum chamber. Electrode layers for either a polymer or small molecule OPV cell may be formed by thermally evaporating metallic contacts in a vacuum chamber.

As now can be appreciated, in different embodiments, a photovoltaic cell may include a transparent substrate, a transparent polymeric nanostructure printed on the substrate, a transparent conductive film formed over the nanostructure on the substrate, an organic photoactive layer above the transparent conductive film, and a conductor above the photoactive layer. The transparent nanostructure and conductive film diffract light transmitted therethrough, and may be structured to provide a grating periodicity of about 100 nm to about 500 nm and a grating amplitude of about 100 nm to about 500 nm. The nanostructure may have nanoscale dimensions in thickness and in one or two other dimensions (such width or length, or both). The nanoscale dimensions may have characteristic sizes larger than about 100 nm and less than about 500 nm. Due to the presence of the nanostructure, the transparent conductive film has textured surfaces including a textured upper surface, which may be periodic textured surfaces. A textured surface is not completely flat but has nanoscale variations. For example, a textured surface may be a corrugated surface, and may have peaks and valleys. The transparent materials in the cell allow sufficient light to transmit therethrough and reach the photoactive layer, so that the photovoltaic cell can properly function.

In use, an OPV cell 700 may be operated as illustrated in FIG. 7. OPV cell 700 may be formed as described above with reference to any of OPV cells 100, 300, 400, 500. In particular, OPV cell 700 has an anode electrode 702 with grating (not shown), a cathode electrode 704, a photoactive layer 706, an optional electron transporting layer 708, an optional hole transporting layer 710, and a substrate 712.

When OPV cell 700 is illuminated by light, as illustrated by the upward pointing arrows in FIG. 7, photo absorption can occur in the cell. Upon photon absorption, excitons are generated in layer 706. Free excitons can migrate to a donor-acceptor interface where they are dissociated into a free electron and free hole. The free electrons and holes can diffuse to layer 708 (electron transporting layer) and layer 710 (hole transporting layer), respectively. Thereafter, charges can be collected at electrode layer 704 (cathode, where electrons are collected) or at electrode layer 702 (anode, where holes are collected). An electric current can thus be produced when electrodes 702 and 704 are electrically connected to form a closed circuit.

It has been recognized that when a grating structure as described herein is provided in an electrode layer of a photovoltaic cell, the grating structure can improve light trapping in the photoactive layer of the cell. It is also expected that the grating structure can increase the optical path length for incident light in an organic layer of the cell. Experimental results show that with a grating structure as described herein, light absorption in an organic photovoltaic cell or device can be increased without increasing of the organic layer thickness. In some tested samples, the PCE of the sample OPV cells or devices has been increased by about 20 to 30% with the addition of a nano-patterned grating structure in the transparent electrode layer of the cell or device. Simulation calculations also show similar improvement consistent with the experimental results.

As alluded to elsewhere, the contributing factors for the observed improvement in PCE may include both increased optical path length of light in the organic photoactive layer and enhanced light absorption in the organic layer due to surface plasmon resonance, and the presence of the nano-grating structure is expected to affect both of these factors.

In comparison, in a conventional OPV cell without a grating structure as described herein, a large portion of the incident light is typically directly reflected back from the OPV cell, and the optical path length in the organic photoactive layer is relatively short (typically less than about 200 nm). Increasing the optical path length with a grating structure in the electrode layer can enhance light absorption quantum efficiency, and thus improve power generation performance.

In some silicon (Si) solar cells, a pyramidal surface texture could be used to scatter light into the solar cell over a large angular range, thereby increasing the effective optical path length in the cell. The size of the pyramidal structure is much more than micron scale. However, in OPV cells, particularly those formed with thin films, large sized structures such as those that have been used in Si solar cells are not suitable due to their large size.

Without being limited to any theory, it is noted that localized plasmon resonance may be induced by incident light at the interface of suitable layer materials, such as at the surface of a nano-patterned grating layer. Among other factors, the wavelength of plasmon resonance is dependent on the size and shape of the nano-patterned structure. Under plasmon resonance conditions, the local electric field around the nano-patterned structure can be strongly enhanced. This field can aid the absorption of light in an OPV device, thus improving its PCE. Thus, the size and shape of the grating structure may be selected and controlled to enhance plasmon resonance.

Some metal grating structures have been proposed in the literature, which are typically formed between a conductive layer such as ITO layer and the photoactive layer. The metal grating may be formed on the ITO layer. However, a metallic grating layer tends to reflect a substantial portion of the incident light, thus significantly reducing the amount of light that can reach the photoactive layer. In comparison, a transparent polymer grating structure to be embedded in a conductive layer can be conveniently printed directly onto a substrate such as a glass substrate, which can reduce reflected light as compared to metallic gratings.

As can be appreciated, an OPV cell or device described herein may be useful and have various applications in electronic devices including optoelectronic devices. Some example devices or applications include OLED, PLED, and other OPV devices or applications.

Example embodiments described herein can be used in OPV devices, such as organic solar cells, organic photo-detectors and organic photo-sensors. They can also be used in products such as optical sensors, biological sensors, medical optoelectronics sensors, chemical sensors, optical attenuators, modulators, optical switches, or the like.

It can also be appreciated that the above example embodiments are provided to illustrate the possible configurations and construction of OPV cells or devices wherein a nano-grating structure can be incorporated. Many variations and modifications are possible while still obtaining improved performance, such as increased PCE. For example, some functional layers in the OPV cell may be formed from either inorganic materials or organic materials, or mixtures of different materials. Additional functional layers or coatings may be provided in any given layer or between different layers described above. Either organic or inorganic hole/electron transporting layers, or hole/electron injector/collectors, may be provided.

In some embodiments, an encapsulation layer (not shown) may also be provided over an outer electrode layer such as electrode layers 304, 404, 504. The encapsulation layer may be a transparent protective layer, and may include, for example, one or more of the following materials: ZnO, SnO₂, In₂O₃, Al₂O₃, NiO, CaF₂, and any organic or inorganic materials that are suitable for applications in grating. The transparent protective layer may also be a transparent conducting layer.

In some embodiments, an OPV cell may be provided on an opaque substrate, which may be formed from either organic or inorganic materials. A substrate for the OPV cell may be formed of an organic or inorganic wafer, a metal foil, or a metal layer laminated onto a plastic foil.

In some embodiments, the order of the layers in an OPV cell or device may be inverted from those shown in the figures.

In some embodiments where a transparent conducting layer is provided, the transparent conducting layer may include a transparent conducting oxide, such as ITO, zinc-indium-oxide, aluminum-doped zinc oxide, Ga—In—Sn—O, SnO₂, Zn—In—Sn—O, Ga—In—O, TiNbO, ZSO, NiOₓ, or any combination of transparent conducting oxides.

In different embodiments, a transparent conducting layer may also be formed from an ultra-thin metallic or modified metallic material, such as Au, Ag/CFₓ or other transparent conducting layer suitable for applications in OPV devices and organic photovoltaic devices.

The nano-pattern of the grating structure may be either one-dimensional (1D) or two-dimensional (2D). For example, ridges 110 may be replaced with islands arranged in a two dimensional pattern, such as to form a checkerboard pattern. The islands may have generally square, rectangular, circular, or other shapes.

It should be understood that the specific embodiments described herein are for illustration purposes. Modifications to these embodiments are possible.

Exemplary embodiments of the present invention are further illustrated with the following examples, which are not intended to be limiting.

### EXAMPLES

### Example I

### Sample Base Structures

Sample base structures (Sample I) were prepared as follows.

A PMMA grating structure was formed on a glass substrate by nanoimprinting. The ridges of the grating structure had an average thickness of about 100 nm. The distance between adjacent ridges and the width of each ridge were both about 250 nm.

A 100 nm thick PMMA (2.5% wt in toluene) was spin-coated onto a glass substrate. The coated substrate was annealed at 120° C. for 2 min. A Si mold with a grating pattern was pressed onto the PMMA coated substrate at a pressure of 60 bars at 140° C. A grating structure was obtained after releasing the mold. The dimensions and shapes of grating structure were controlled by the Si mold.

A high performance LT-ITO anode layer was overlaid on the PMMA grating structure and on the glass substrate at a low processing temperature of less than 60° C., to form the sample base structure. The LT-ITO layer had a thickness of about 130 nm. Due to the presence of the PMMA grating structure, the top surface of the LT-ITO layer had a wave-like profile.

The high performance LT-ITO anode layer was deposited with a combination of RF and DC sputtering, at a low processing temperature of less than 60° C. The deposition rate was about 4 nm/s and the entire ITO thickness was approximately 130 nm.

The resulting Sample I base structure is as schematically illustrated in FIG. 6.

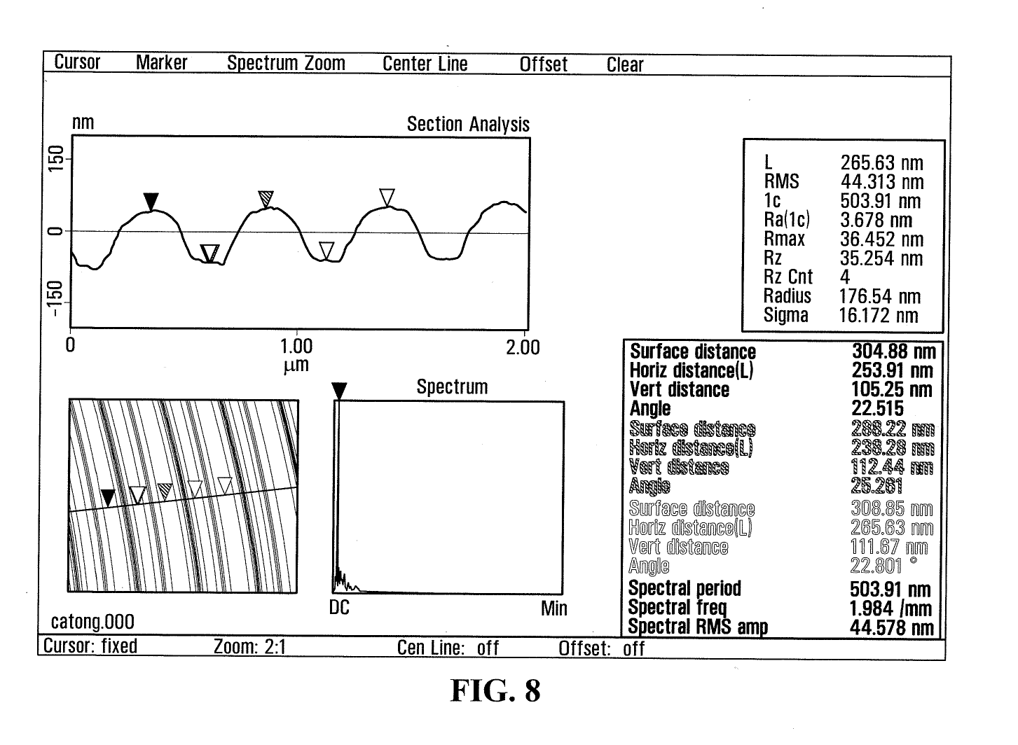

Atomic Force Microscopy (AFM) images of the sample resulting structures were obtained and a representative screen shot of an AFM image is depicted in FIG. 8. As can be seen from FIG. 8, the grating structure had a periodicity of about 500 nm and amplitude of about 110 nm.

The ITO layer was expected to exhibit relatively high electric conductivity and optical transparency, as a similarly prepared 130 nm ITO film was found to exhibit an electrical sheet resistance of 25±5 Ω/sq and an average light transmittance of above 85%.

### Example II

### OPV structure with Small Molecule OPV Material

A layer of a small molecule material, ZnPc:C₆₀, was thermally deposited on the ITO layer of a Sample I base structure.

A p-type material (ZnPc) and an n-type material (C₆₀) were deposited onto the ITO sample by thermal evaporation in high vacuum. The weight ratio of the two materials was 1:1. These materials were purchased from commercial sources.

The electron transporting layer (n-type material C₆₀) and electron injection layer were deposited via thermal evaporation in high vacuum. These materials were also purchased from commercial sources.

The resulting sample OPV structure (Sample II) is schematically shown in FIG. 5.

Sample II structure had a 150 nm thick LT-ITO layer, a 40 nm thick ZnPc:C₆₀ layer, a 28.6 nm C₆₀ layer, a 8 nm thick BPhen layer, a 120 nm thick Ag layer. As the total thickness of the organic layers was less than 80 nm, the organic layers conformed to the morphology of the underlying structure, and had a wave-like profile.

### Example III

### OPV structure with Polymer OPV Material

A layer of a polymer material, P3HT:PCBM, was thermally deposited on the ITO layer of a Sample I base structure.

P3HT and PCBM were mixed with a weight ratio of 1:0.8 in dichlorobenzene (DCB), with a total concentration of 36 mg/ml. The mixture was prepared in an inert environment. The solution was spin-coated onto the substrate to form a film with a thickness of 200 nm.

A PEDOT:PSS mixture was spin-coated onto the ITO layer, forming a layer with a thickness of about 40 nm.

The above materials were purchased from commercial sources.

The resulting OPV structure (Sample III) is schematically shown in FIG. 4.

As shown, Sample III structure had a 150 nm thick LT-ITO layer, a 40 nm thick PEDOT:PSS layer, a 200 nm thick P3HT:PCBM layer, and a 10 nm thick Ca layer and a 100 nm thick Ag layer. As the thickness of the polymer layers was sufficiently thicker than the underlying grating structure, the polymer layers had a generally flat top surface.

### Example IV

The current density-voltage (J-V) characteristics of the Samples II and III were measured under a simulated AM1.5G illumination at an intensity of 100 mW/cm². Characterizations of the samples were performed in a nitrogen atmosphere. The light source intensity was calibrated using a KG-5 filtered photodiode.

For comparison, control samples were also prepared. The control samples were formed as in Examples I, II and III except that a flat PMMA layer was formed on the glass substrate instead of a PPMA grating structure in the control samples.

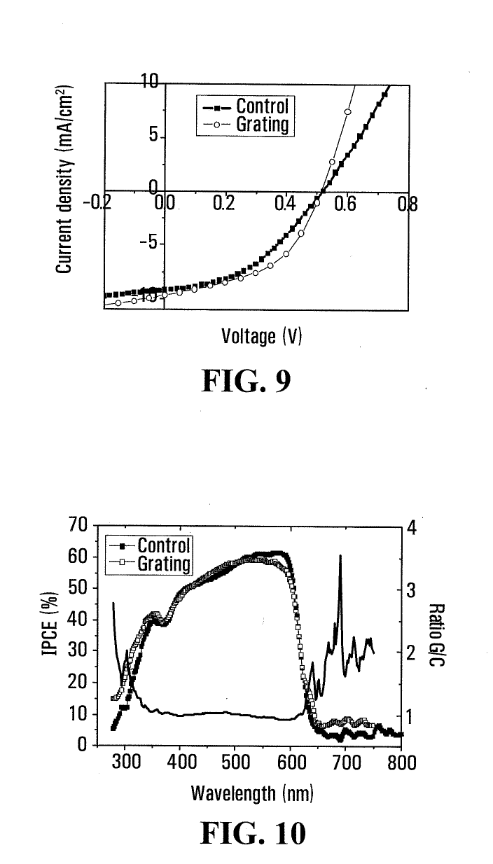

Representative results of J-V characteristics of Samples II and III and the control samples are shown in FIGS. 9, 10, 11 and 12.

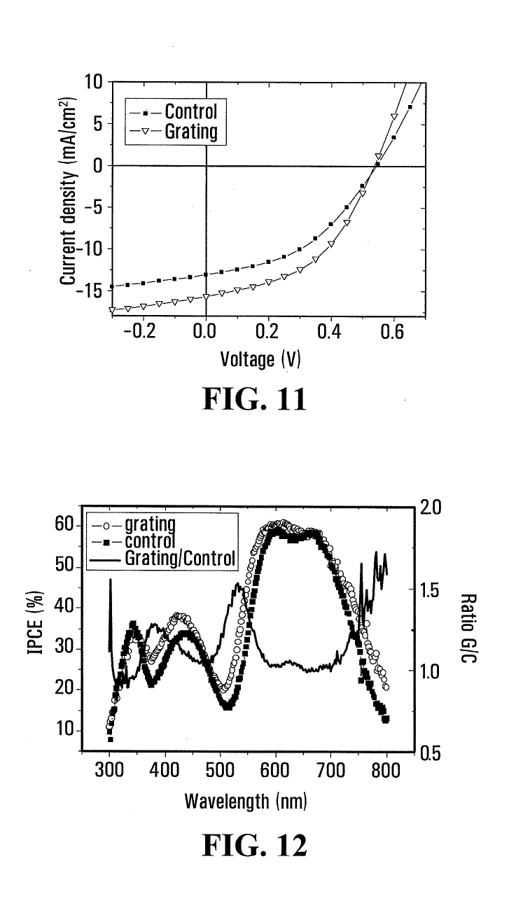

FIGS. 9 and 10 show results measured from Sample III (data represented by circles or hollow squares) and its corresponding control sample (data represented by solid squares). FIGS. 11 and 12 show results measured from Sample II (data represented by circles or hollow triangles) and its corresponding control sample (data represented by solid squares). In FIGS. 10 and 12, the solid line indicates the ratio of IPCE between the sample with grating (G) and the control sample (C).

The results showed that Sample III OPV cells exhibited better performance than the control samples with the same polymeric layer. The incident photon-to-electron conversion efficiencies (IPCE) in both samples from λ=300 nm to 800 nm were measured and the results are shown in FIG. 10. The short circuit current and fill factor in Sample III had higher values. The higher short circuit current was expected to be due to enhanced photon absorption. The grating structure was expected to increase the optical path length of the incoming light. It was also expected that the increase in interfacial area for exciton dissociation contributed to the increased current. The higher fill factor was expected to originate from the lower sheet resistance arising from thinner organic layers. The open-circuit voltages (V_{oc}) were similar for both samples, which was expected because the V_{oc} was mainly determined by the highest occupied molecular orbital (HOMO) of the donor and the lowest unoccupied molecular orbital (LUMO) of the acceptor, which were the same in both Samples.

It was also found that the nano-periodic grating structure of Sample II enhanced power generation of the OPV cell. FIG. 11 shows the J-V characteristics of the Sample II and its corresponding control sample. Sample II with the grating structure exhibited better performance than the control OPV device. The IPCE of both devices were measured and the results are shown in FIG. 12. From the experimental results, the short circuit current and fill factor in grating incorporated OPV devices display higher values. The higher short circuit current is due to extra photon absorption. The grating serves to increase the optical path length of the incoming light. It can also be attributed to the increase in interfacial area for exciton dissociation. Surface plasmon resonance may also play a role. The higher fill factor originated from the lower sheet resistance arising from thinner organic layers in the OPV device.

Results obtained from both polymeric and organic small molecule OPV cells showed that a nano-grating structure could enhance light absorption due to light coupling. Surface plasmon resonance can also contribute to the overall enhancement. This is especially true for thinner organic layers.

In each Sample II or III OPV structures, a Λ=500 nm one dimensional (1D) grating was provided. The photovoltaic properties of the sample OPV structures were measured under a simulated AM 1.5 G illumination at an intensity of 100 mW/cm² and the results are summarized in Table I and Table II.

It was observed that the tested samples with a grating pattern had the best performance.

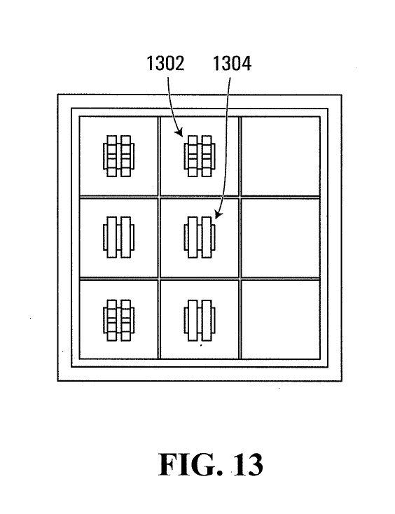

FIG. 13 depicts a top view of a sample OPV device with both Sample II structure 1302 with grating and corresponding control sample structure 1304 without grating, which was used in the testing.

TABLE 1
Measured data for Sample II and corresponding Control Sample

| | V_{oc} | J_{sc} | FF | PCE |
|---|---|---|---|---|
| Sample | (V) | (mA/cm²) | (%) | (%) |
| Control | 0.54 | 13.04 | 43.3 | 3.07 |
| Sample II | 0.54 | 15.68 | 46.7 | 3.93 |

TABLE 2
Measured data for Sample III and corresponding Control Sample

| | V_{oc} | J_{sc} | FF | PCE |
|---|---|---|---|---|
| Sample | (V) | (mA/cm²) | (%) | (%) |
| Control Sample | 0.52 | 9.19 | 43.0 | 2.06 |
| Sample III | 0.52 | 9.70 | 48.8 | 2.46 |

Simulation calculations were also performed and the simulation results were consistent with the experimental data. A 20-30% improvement in the PCE of the OPV structures with grating over the control OPV structures with a flat PPMA layer was observed.

It will be understood that any range of values herein is intended to specifically include any intermediate value or sub-range within the given range, and all such intermediate values and sub-ranges are individually and specifically disclosed.

It will also be understood that the word “a” or “an” is intended to mean “one or more” or “at least one”, and any singular form is intended to include plurals herein.

It will be further understood that the term “comprise”, including any variation thereof, is intended to be open-ended and means “include, but not limited to,” unless otherwise specifically indicated to the contrary.

When a list of items is given herein with an “or” before the last item, any one of the listed items or any suitable combination of two or more of the listed items may be selected and used.

Of course, the above described embodiments are intended to be illustrative only and in no way limiting. The described embodiments are susceptible to many modifications of form, arrangement of parts, details and order of operation. The invention, rather, is intended to encompass all such modification within its scope, as defined by the claims.

1. A photovoltaic cell comprising:
a first electrode layer and a second electrode layer;
an organic photoactive layer between said first and second electrode layers; and
a polymeric grating structure in said first electrode layer,
wherein said first and second electrode layers are configured to collect electrical charges from said photoactive layer and to allow light to transmit through said first electrode layer to reach said photoactive layer, and said grating structure is configured to provide a grating periodicity of about 100 nm to about 500 nm and a grating amplitude of about 100 nm to about 500 nm.

2. The photovoltaic cell of claim 1, wherein said polymeric grating structure is formed from a poly(methyl methacrylate).

3. The photovoltaic cell of claim 1, wherein said first electrode layer comprises a transparent conducting oxide.

4. The photovoltaic cell of claim 3, wherein said transparent conducting oxide is indium-tin-oxide.

5. The photovoltaic cell of claim 3, wherein said first electrode layer has a thickness of about 100 nm to about 500 nm.

6. The photovoltaic cell of claim 1, wherein said polymeric grating structure is printed on a substrate, and said first electrode layer is formed on said substrate and said polymeric grating structure.

7. The photovoltaic cell of claim 6, wherein said substrate is formed of glass.

8. The photovoltaic cell of claim 1, wherein said organic photoactive layer comprises a polymeric photoactive material or a small molecule photoactive material.

9. The photovoltaic cell of claim 1, comprising a charge transporting layer disposed between said photoactive layer and one of said first and second electrode layers.

10. A device comprising the photovoltaic cell of claim 1.

11. A method of forming a photovoltaic cell, comprising:
printing a polymer on a substrate to form a grating structure;
forming a first electrode layer on said polymeric grating structure and said substrate;
forming an organic photoactive layer above said first electrode layer; and
forming a second electrode layer above said photoactive layer,
wherein said first electrode layers allows transmission of light therethrough to reach said photoactive layer, and said grating structure provides a grating periodicity of about 100 nm to about 500 nm and a grating amplitude of about 100 nm to about 500 nm.

12. The method of claim 11, wherein said polymer is a poly(methyl methacrylate).

13. The method of claim 11, wherein said first electrode layer comprises a transparent conducting oxide.

14. The method of claim 13, wherein said transparent conducting oxide is indium-tin-oxide.

15. The method of claim 14, wherein said first electrode layer is formed at a temperature below 60° C. by sputtering.

16. The method of claim 13, wherein said first electrode layer is formed to have a thickness of about 100 nm to about 500 nm.

17. The method of claim 11, wherein said substrate is formed of glass.

18. The method of claim 11, wherein said organic photoactive layer comprises a polymeric photoactive material or a small molecule photoactive material.

19. The method of claim 11, comprising forming a charge transporting layer between said photoactive layer and one of said first and second electrode layers.

20. A photovoltaic cell comprising:
a transparent substrate;
a transparent polymeric nanostructure printed on said substrate;
a transparent conductive film formed over said nanostructure on said substrate, said film having a textured surface;
an organic photoactive layer above said film; and
a conductor above said photoactive layer,
wherein said nanostructure and said film diffract light transmitted therethrough.

21. The method of claim 9, comprising forming a charge transporting layer between said photoactive layer and one of said first and second electrode layers.
